(19) United States
(12) Patent Application Publication
(10) Pub. No.: US 2013/0194006 A1
(43) Pub. Date: Aug. 1, 2013

(54) DEAD TIME GENERATION CIRCUIT AND LOAD DRIVING APPARATUS

(71) Applicant: DENSO CORPORATION, Kariya-city (JP)

(72) Inventor: Akinori YAMAMOTO, Chiryu-city (JP)

(73) Assignee: DENSO CORPORATION, Kariya-city (JP)

(21) Appl. No.: 13/738,236

(22) Filed: Jan. 10, 2013

(30) Foreign Application Priority Data
Jan. 26, 2012 (JP) 2012-14103

(51) Int. Cl. H03K 3/013

(52) U.S. Cl. CPC H03K 3/013
USPC 327/109; 327/296

(57) ABSTRACT

A dead time generation circuit includes a high-side control signal generation circuit and a low-side control signal generation circuit which are separate circuits. The high-side control signal generation circuit inverts a level of a high-side control signal from a driving prohibition level to a driving permission level when a time corresponding to a first clock number has elapsed in a state where a control signal keeps a first level after the control signal transitions from a second level to the first level. The low-side control signal generation circuit inverts a level of a low-side control signal from the driving prohibition level to the driving permission level when a time corresponding to a second clock number has elapsed in a state where the control signal keeps the second level after the control signal transitions from the first level to the second level.

### CROSS REFERENCE TO RELATED APPLICATIONS

The present application is based on and claims priority to Japanese Patent Application No. 2012-14103 filed on Jan. 26, 2012, the contents of which are incorporated in their entirety herein by reference.

### TECHNICAL FIELD

The present disclosure relates to a dead time generation circuit and a load driving apparatus including the dead time generation circuit.

### BACKGROUND

A bridge circuit is an output circuit in which a high-side transistor and a low-side transistor are coupled in series between driving power lines. A load driving apparatus receives a control signal of one line, generates a high-side driving signal and a low-side driving signal, and drives the high-side transistor and a low-side transistor using the high-side driving signal and the low-side driving signal. In order to restrict an arm short circuit, it is required to set dead times at a state transition when the low-side transistor is turned off and the high-side transistor is turned on (hereafter, referred to as a state transition of high-side on) and a state transition when the high-side transistor is turned off and the low-side transistor is turned on (hereafter, referred to as a state transition of low-side on).

The load driving apparatus generates a high-side control signal and a low-side control signal with a logic circuit and the like whose reference potential is the ground. The low-side control signal is transmitted to a gate of the low-side transistor as the low-side driving signal while keeping the reference potential. Because the high-side transistor is coupled between the driving power line on the high-side and an output terminal, the high-side control signal is transmitted to a gate of the high-side transistor as a high-side driving signal after a level shift. A level shift circuit may cause a delay of the high-side control signal.

JP-A-2005-143282 discloses a dead time generation circuit including a D flip-flop that synchronizes a pulse width modulation (PWM) signal with a clock and a D flip-flop that generates a delay for a half period of the clock at a subsequent stage. The dead time generation circuit generates a high-side driving signal based on Q1 output from a first stage and /Q2 output from a second stage and generates a low-side driving signal based on /Q1 output from the first stage and Q2 output from the second stage. JP-A-2005-184543 discloses a dead time generation circuit that generates a high-side driving signal by passing a PWM signal through a delay circuit of a first stage and generates a low-side driving signal by passing the high-side driving signal through a delay circuit of a second stage and operating AND with PWM signal (and the high-side driving signal).

The dead time generation circuit disclosed in JP-A-2005-143282 cannot set the dead time at the state transition of high-side on and the dead time at the state transition of low-side on separately. Thus, in cases where a delay time of a drive circuit is different between a high-side and a low-side, as a drive circuit including a level shift circuit, a dead time of a voltage output from the output circuit is different between a time when the high-side is turned on and a time when the low-side is turned on. As a result, distortion is generated in a sine waveform output by sine-wave PWM driving.

The dead time generation circuit disclosed in JP-A-2005-143282 has a configuration in which D flip-flops are merely coupled in multiple stages. The dead time generation circuit disclosed in JP-A-2005-184543 has a configuration in which the signal obtained by delaying the PWM signal is used as the high-side driving signal. In the above-described configurations, when a noise signal having waveform as chattering is superimposed on the PWM signal, an abnormal driving signal without the dead time may be output.

### SUMMARY

It is an object of the present disclosure to provide a dead time generation circuit that can set a dead time at a high-side on and a dead time at a low-side on separately and can restrict output of an abnormal high-side control signal and an abnormal low-side control signal even when a noise signal is superimposed on a control signal. Another object of the present disclosure is to provide a load driving apparatus including the dead time generation circuit.

A dead time generation circuit according to a first aspect of the present disclosure includes a high-side control signal generation circuit and a low-side control signal generation circuit. The high-side control signal generation circuit controls a level of a high-side control signal to a driving prohibition level when a level of a control signal is a second level and inverts the level of the high-side control signal to a driving permission level when a time corresponding to a first clock number has elapsed in a state where the control signal keeps a first level after the control signal transitions from the second level to the first level. The low-side control signal generation circuit controls a level of a low-side control signal to the driving prohibition level when the level of the control signal is the first level and inverts the level of the low-side control signal to the driving permission level when a time corresponding to a second clock number has elapsed in a state where the control signal keeps the second level after the control signal transitions from the first level to the second level. The high-side control signal generation circuit and the low-side control signal generation circuit are separate circuits.

The dead time generation circuit can set a dead time at a state transition of high-side on and a dead time at a state transition of low-side on separately and can restrict output of an abnormal high-side control signal and an abnormal low-side control signal without securing required dead times, even when a noise signal is superimposed on the control signal.

A load driving apparatus according to a second embodiment of the present disclosure includes a dead time generation circuit according to the first aspect, a high-side driving circuit, a low-side driving circuit, and an output circuit. The high-side driving circuit receives the high-side control signal transmitted from the dead time generation circuit and transmits a high-side driving signal. The low-side driving circuit receives the low-side control signal transmitted from the dead time generation circuit and transmits a low-side driving signal. The output circuit includes a high-side transistor driven by the high-side driving signal, a low-side transistor driven by the low-side driving signal, driving power lines, and an output terminal. The high-side transistor and the low-side transistor form a bridge connection between the driving power lines across the output terminal.

Even in cases where the high-side driving circuit and the low-side driving circuit have different delay times, the load driving apparatus can equalize a dead time on a high side and a dead time on a low side.

### BRIEF DESCRIPTION OF THE DRAWINGS

Additional objects and advantages of the present disclosure will be more readily apparent from the following detailed description when taken together with the accompanying drawings. In the drawings:

FIG. 1 is a diagram showing a load driving apparatus according to a first embodiment of the present disclosure;

FIG. 2 is a timing diagram of a high-side driving circuit;

FIG. 3 is a timing diagram of a control signal Xin, a high-side control signal XH, and a low-side control signal XL;

FIG. 4 is a timing diagram of a clock CLK, the control signal Xin, signals Sb-Sd, the high-side control signal XH, and the low-side control signal XL;

FIG. 5A and FIG. 5B are timing diagrams of the control signal Xin, the high-side control signal XH, and the low-side control signal XL in cases where the control signal Xin is a narrow pulse;

FIG. 6A and FIG. 6B are timing diagrams of the control signal Xin, the high-side control signal XH, and the low-side control signal XL in cases where a noise signal having a narrow width is superimposed on the control signal Xin;

FIG. 7 is a timing diagram of the control signal Xin, the high-side control signal XH, the low-side control signal XL, a high-side gate signal GH, and a low-side gate signal GL;

FIG. 8 is a diagram showing a dead time generation circuit according to a second embodiment of the present disclosure;

FIG. 9 is a timing diagram of a control signal Xin, a signal Sa1, a high-side control signal XH, and a low-side control signal XL in the dead time generation circuit according to the second embodiment;

FIG. 10 is a timing diagram of a clock CLK, the control signal Xin, the signal Sa1, signals Sb-Sd, the high-side control signal XH, and the low-side control signal XL in the dead time generation circuit according to the second embodiment;

FIG. 11A and FIG. 11B are timing diagrams of the control signal Xin, the high-side control signal XH, and the low-side control signal XL in the dead time generation circuit according to the second embodiment in cases where the control signal Xin is a narrow pulse;

FIG. 12A and FIG. 12B are timing diagrams of the control signal Xin, the high-side control signal XH, and the low-side control signal XL in the dead time generation circuit according to the second embodiment in cases where a noise signal having a narrow width is superimposed on the control signal Xin;

FIG. 13 is a timing diagram of the control signal Xin, the high-side control signal XH, the low-side control signal XL, a high-side gate signal GH, and a low-side gate signal GL in a load driving apparatus according to the second embodiment;

FIG. 14 is a diagram showing a dead time generation circuit according to a third embodiment of the present disclosure;

FIG. 15 is a timing diagram of a control signal Xin, a signal Sa2, a high-side control signal XH, and a low-side control signal XL in the dead time generation circuit according to the third embodiment; and

FIG. 16 is a timing diagram of a clock CLK, the control signal Xin, the signal Sa2, signals Sb-Sd, the high-side control signal XH, and the low-side control signal XL in the dead time generation circuit according to the third embodiment.

### DETAILED DESCRIPTION

### First Embodiment

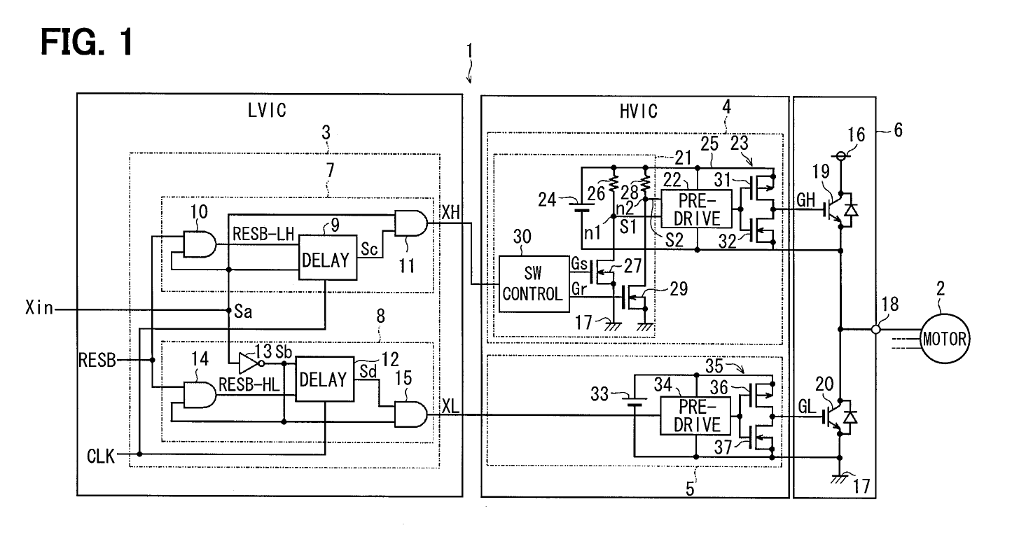

A first embodiment of the present disclosure will be described with reference to FIG. 1 to FIG. 7. A load driving apparatus 1 shown in FIG. 1 is an inverter equipment that performs a PWM driving of a motor 2. The motor 2 is a three-phase permanent magnet synchronous motor for driving a compressor in a hybrid vehicle based on control signals Uin, Vin, Win (hereafter, a control signal of X-phase is referred to as Xin) transmitted from an in-vehicle electronic control unit (ECU). In order to avoid complication, only a configuration of one phase (X-phase) in three phases is shown in FIG. 1. In the following description, an H level and an L level of the control signal Xin respectively correspond to a first level and a second level.

The load driving apparatus 1 includes a dead time generation circuit 3, a high-side driving circuit 4, a low-side driving circuit 5, and an output circuit 6. The dead time generation circuit 3 is configured as a complementary metal-oxide semiconductor (CMOS) low-voltage integrated circuit (LVIC). The high-side driving circuit 4 and the low-side driving circuit 5 are configured as a CMOS high-voltage integrated circuit (HVIC).

The dead time generation circuit 3 includes a high-side control signal generation circuit 7 and a low-side control signal generation circuit 8 which are independent from each other. In other words, the high-side control signal generation circuit 7 and the low-side control signal generation circuit 8 are separate circuits. The high-side control signal generation circuit 7 generates a high-side control signal XH. The low-side control signal generation circuit 8 generates a low-side control signal XL. When the high-side control signal XH and the low-side control signal XL are at the H level corresponding to a driving permission level, switching elements (e.g., insulated-gate bipolar transistors (IGBTs) 19, 20) in the output circuit 6 are respectively activated. When the high-side control signal XH and the low-side control signal XL are at the L level corresponding to a driving prohibition level, the switching elements in the output circuit 6 are respectively deactivated.

A reset signal RESB is transmitted from a reset circuit (not shown) for restricting a malfunction at a time when a supply voltage of the CMOS circuits is reduced. The reset signal RESB transitions to the H level when the supply voltage is within a level with which the CMOS circuits can operate normally. The reset signal RESB transitions to the L level when the supply voltage is reduced to a level with which the CMOS circuits cannot operate normally.

The high-side control signal generation circuit 7 includes a delay circuit 9 and AND gates 10, 11. The delay circuit 9 transmits a signal Sc which is obtained by delaying the control signal Xin (hereafter, also referred to as a signal Sa) for the first clock number (e.g., 7 clocks) in synchronization with up-edges of a clock (CLK). The AND gate 10 receives the signal Sa and the reset signal RESB. The delay circuit 9 resets the signal Sc to the L level when a reset signal RESB-LH transmitted from the AND gate 10 transitions to the L level. The AND gate 11 receives the signal Sa and the signal Sc and transmits the high-side control signal XH.

The low-side control signal generation circuit 8 includes a delay circuit 12, an inverter 13 and AND gates 14, 15. The inverter 13 transmits a signal Sb which is obtained by inverting the control signal Xin. The delay circuit 12 transmits a signal Sd which is obtained by delaying the signal Sb for a second clock number (e.g., 9 clocks) in synchronization with up-edges of the clock. The AND gate 14 receives the signal Sb and the reset signal RESB. The delay circuit 12 resets the signal Sd to the L level when a reset signal RESB-HL transmitted from the AND gate 14 transitions to the L level. The AND gate 15 receives the signal Sb and the signal Sd and transmits the low-side control signal XL.

The output circuit 6 includes direct current power lines 16, 17 as driving power lines, an output terminal 18, and the IGBTs 19, 20. The IGBT 19 (high-side transistor) and the IGBT 20 (low-side transistor) form a bridge connection between the direct current power lines 16, 17 across the output terminal 18. A winding terminal of the motor 2 is coupled with the output terminal 18. The high-side driving circuit 4 that drives the IGBT 10 includes a level shift circuit 21, a pre-driving circuit (PRE-DRIVE) 22, and a driving circuit 23.

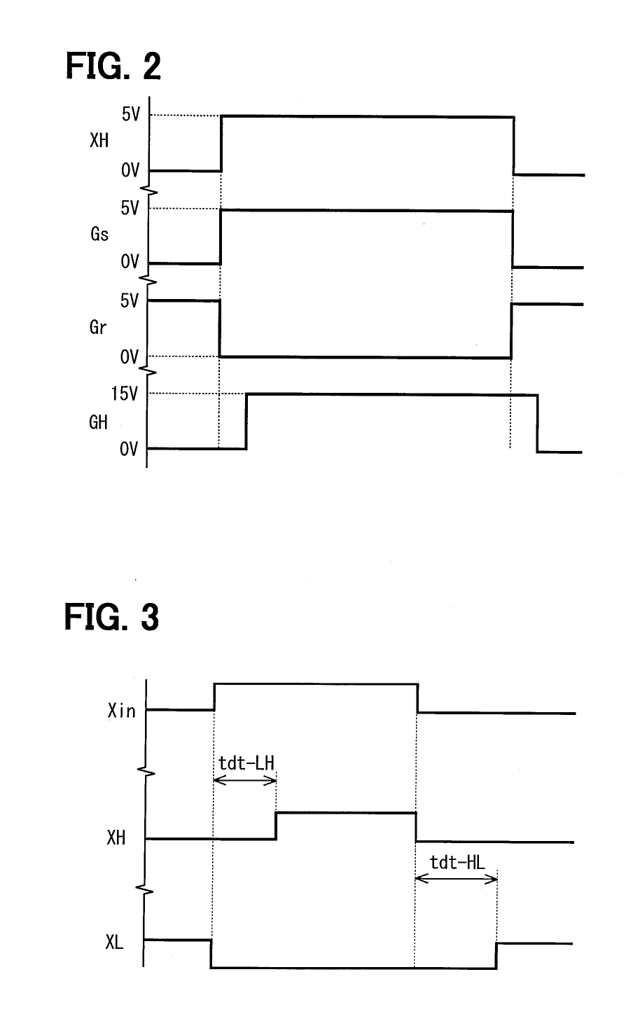

The level shift circuit 21 includes a driving power source 24 of 15 V. A reference potential of the driving power source 24 is set to an emitter (output terminal 18) of the IGBT 19. Between a high-potential side power line 25 of the driving power source 24 and the direct current power line 17, a series circuit of a resistor 26 and a metal-oxide-semiconductor (MOS) transistor 27 and a series circuit of a resistor 28 and a MOS transistor 29 are coupled. FIG. 2 is a timing diagram of the high-side driving circuit 4.

When the high-side control signal XH transitions to the H level (5 V), a switching control circuit (SW CONTROL) 30 sets a gate signal Gs of the MOS transistor 27 to the H level and a gate signal Gr of the MOS transistor 29 to the L level. At this time, a signal S1 of a node n1 transitions to the L level, a signal S2 of a node n2 transitions to the H level, and the pre-driving circuit 22 turns on a MOS transistor 31 in the driving circuit 23 and turns off a MOS transistor 32 in the driving circuit 23. Accordingly, the driving circuit 23 transmits a gate signal GH (high-side driving signal) of 15 V so as to activate the IGBT 19.

When the high-side control signal XH transitions to the L level (0 V), the switching control circuit 30 sets the gate signal Gs to the L level and the gate signal Gr to the H level. At this time, the signal S1 transitions to the H level, the signal S2 transitions to the L level, and the pre-driving circuit 22 turns off the MOS transistor 31 and turns on the MOS transistor 32. Accordingly, the driving circuit 23 transmits the gate signal GH of 0 V so as to deactivate the IGBT 19.

The low-side driving circuit 5 for driving the IGBT 20 includes a driving power source 33 of 15 V, a pre-driving circuit 34, and a driving circuit 35. When a low-side control signal XL transitions to the H level (5 V), the pre-driving circuit 34 turns on a MOS transistor 36 in the driving circuit 35 and turns off a MOS transistor 37 in the driving circuit 35. Accordingly, the driving circuit 35 transmits a gate signal GL (low-side driving signal) of 15 V so as to activate the IGBT 20. When the low-side control signal XL transitions to the L level (0 V), the pre-driving circuit 34 turns off the MOS transistor 36 and turns on the MOS transistor 37. Accordingly, the driving circuit 35 outputs the gate signal of 0 V so as to deactivate the IGBT 20.

An operation of the dead time generation circuit 3 according to the present embodiment will be described with reference to FIG. 3 to FIG. 7. As shown in FIG. 3, when the control signal Xin rises from the L level to the H level, the low-side control signal XL immediately transitions to the L level. Then, after a dead time tdt-LH has elapsed from a rising edge, the high-side control signal XH transitions to the H level. Similarly, when the control signal Xin falls from the H level to the L level, the high-side control signal XH immediately transitions to the L level. Then, after a dead time tdt-HL has elapsed from a falling edge, the low-side control signal XL transitions to the L level.

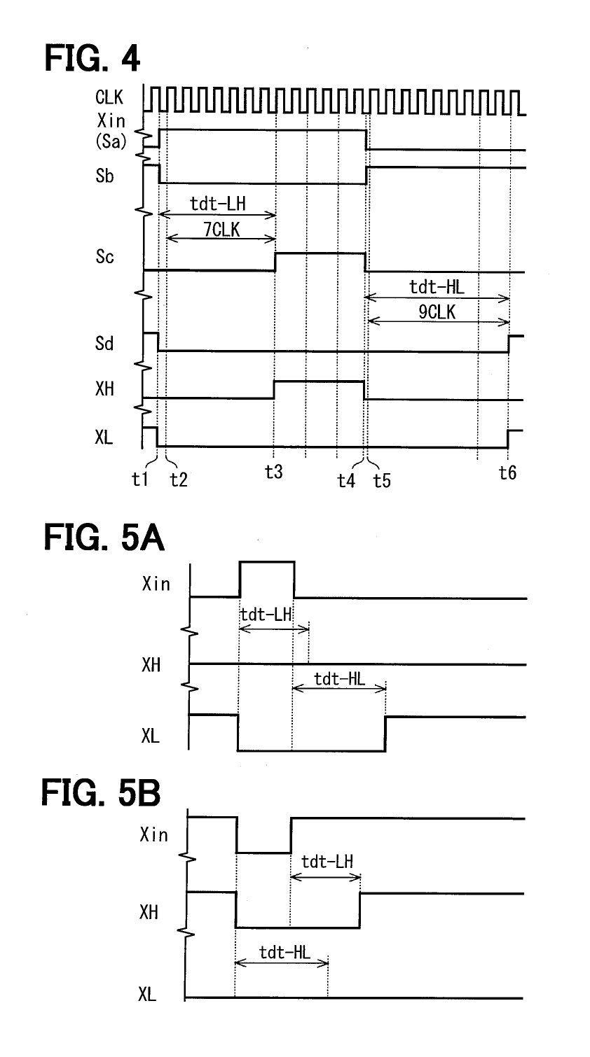

FIG. 4 is a more detailed timing chart. When the control signal Xin rises to the H level at a time t1, the delay circuit 12 immediately changes the level of the low-side control signal XL to the L level. The delay circuit 9 sets a first up-edge of the clock to a reference point (time t2). Then, the delay circuit 9 changes the high-side control signal XH to the H level at time t3 after 7 clocks (i.e., a time corresponding to the first clock number) have elapsed in a state where a reset signal RESB-LH keeps the H level. When the control signal Xin returns to the L level before 7 clocks have elapsed, the high-side control signal XH keeps the L level (see FIG. 5A).

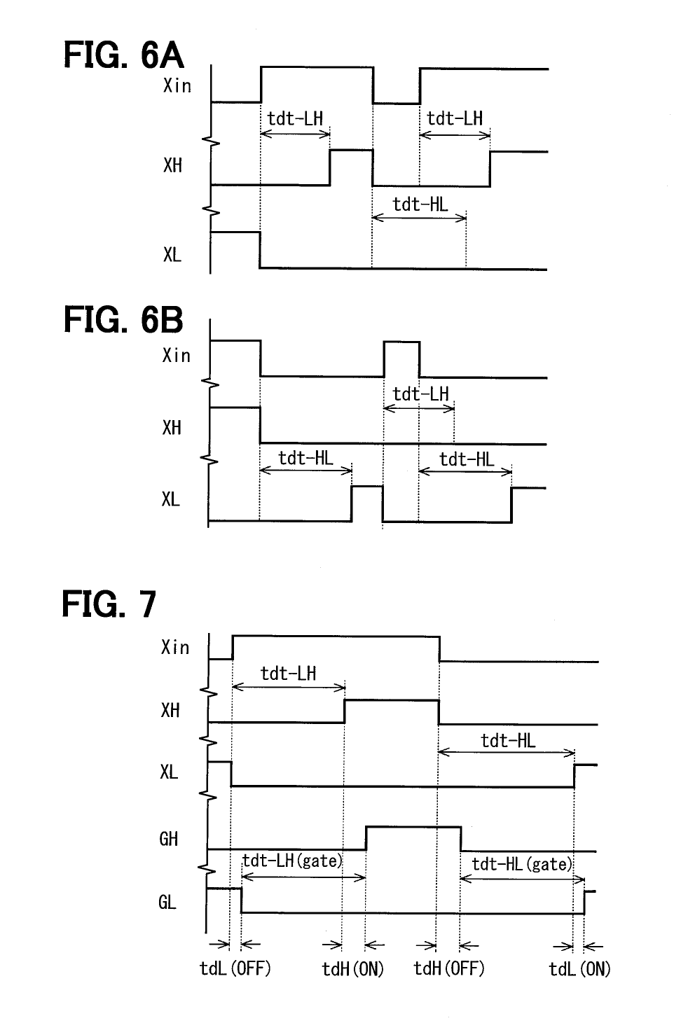

After the high-side control signal XH transitions to the H level, when the reset signal RESB-LH temporarily transitions to the L level due to a noise signal of the L level superimposed on the control signal Xin or a reduction of the supply voltage, the delay circuit 9 immediately changes the level of the high-side control signal XH to the L level. After that, the reset signal RESB-LH returns to the H level and when 7 clocks have elapsed in a state where the RESB-LH keeps the H level, the delay circuit 9 changes the level of the high-side control signal XH to the H level (see FIG. 6A). The dead time tdt-LH of the high-side control signal XH has a width greater than or equal to 7 clocks and less than 8 clocks.

When the control signal Xin rises to the L level at time t4, the delay circuit 9 immediately changes the level of the high-side control signal XH to the L level. The delay circuit 12 sets a first up-edge of the clock to a reference point (time t5). Then, the delay circuit 12 changes the level of the low-side control signal XL to the H level at time t6 after 9 clocks (i.e., a time corresponding to the second clock number) have elapsed in a state where a reset signal RESB-HL keeps the H level. When the control signal Xin returns to the L level before 9 clocks have elapsed, the low-side control signal XL keeps the L level (see FIG. 5B).

After the low-side control signal XL transitions to the H level, when the reset signal RESB-HL temporarily transitions to the L level due to a noise signal of the H level to the control signal Xin or a reduction of the supply voltage, the delay circuit 12 immediately changes the level of the low-side control signal XL to the L level. After that, the reset signal RESB-HL returns to the H level and when 9 clocks have elapsed in a state where the RESB-HL keeps the H level, the delay circuit 12 changes the level of the low-side control signal XL to the H level (see FIG. 6B). The dead time tdt-HL of the low-side control signal XL has a width greater than or equal to 9 clocks and less than 10 clocks.

Because the high-side driving circuit 4 includes the level shift circuit 21, the delay of the high-side driving circuit 4 is larger than the delay of the low-side driving circuit 5. A condition for equalizing the dead times of the gate signals GH, GL of the IGBTs 19, 20 even in cases where the high-side driving circuit 4 and the low-side driving circuit 5 have different delay characteristics will be described with reference to FIG. 7.

The delay time of the high-side driving circuit 4 at a time when the high-side control signal XH rises is expressed as tdH(ON), and the delay time of the high-side driving circuit 4 at a time when the high-side control signal XH falls is expressed as tdH(OFF). The delay time of the low-side driving circuit 5 at a time when the low-side control signal XL rises is expressed as tdL(ON), and the delay time of the low-side driving circuit 5 at a time when the low-side control signal XL falls is expressed as tdL(OFF). At this time, an actual dead time tdt-LH(gate) from when the gate signal GL transitions to the L level to when the gate signal GH transitions to the H level is expressed as the following equation (1).

tdt−LH(gate)=tdt−LH+(tdH(ON)−tdL(OFF)) (1)

Moreover, an actual dead time tdt-HL (gate) from when the gate signal GH transitions to the L level to when the gate signal GL transitions to the H level is expressed as the following equation (2).

tdt−HL(gate)=tdt−HL−(tdH(OFF)−tdL(ON)) (2)

The dead time tdt-LH(gate) and the dead time tdt-HL(gate) can be equal to each other when the following equation (3) is satisfied.

tdt−HL=tdt−LH+(tdH(ON)−tdL(ON))+(tdH(OFF)−tdL(OFF)) (3)

In other words, the dead time tdt-HL of the low-side control signal XL is set to a time calculated by adding a delay time difference between the high-side driving circuit 4 and the low-side driving circuit 5 at turning on and a delay time difference between the high-side driving circuit 4 and the low-side driving circuit 5 at turning off to the dead time tdt-LH of the high-side control signal XH. However, because the dead times tdt-HL, tdt-LH are set on the basis of the period of the clock, an error for 1 clock is generated at the maximum with respect to the first clock number and the second clock number, which are set.

As described above, the dead time generation circuit included in the load driving apparatus 1 according to the present embodiment sets the delay clock numbers of the delay circuits 9, 12 to the first clock number and the second clock number, respectively. Accordingly, using time points of the level transition of the control signal Xin as the reference points, the dead time dt-LH of the high side corresponding to the first clock number and the dead time dt-HL of the low side corresponding to the second clock number can be set separately.

When the first clock number and the second clock number are set in accordance with the delay time difference between the high-side driving circuit 4 and the low-side driving circuit 5 at turning on and the delay time difference between the high-side driving circuit 4 and the low-side driving circuit 5 at turning off, the dead times of the high side and the low side actually appeared in the gate signals GH, GL of the IGBTs 19, 20 can be equal to each other with respect to the two state transitions of “the high-side on” and “the low-side on.” As a result, when the load driving apparatus 1 drives the motor 2 with the sine wave PWM signal, distortion in the output sine wave due to the dead times can be reduced.

When the control signal Xin is inverted to the L level due to, for example, a noise signal, before a time corresponding to the first clock number has elapsed from a time when the control signal Xin transitions to the H level, the delay circuit 9 resets the delay operation synchronized with the clock. Thus, the high-side control signal XH does not transition to the H level without securing a required dead time. Similarly, when the control signal Xin is inverted to the H level due to, for example, a noise signal, before a time corresponding to the second clock number has elapsed from a time when the control signal Xin transitions to the L level, the delay circuit 12 resets the delay operation synchronized with the clock. Thus, the low-side control signal XL does not transition to the H level without securing a required dead time. In this way, even when a noise signal is superimposed on the control signal Xin or when the supply voltage decreases temporarily, the load driving apparatus 1 does not transmit an abnormal high-side control signal XH and an abnormal low-side control signal XL.

### Second Embodiment

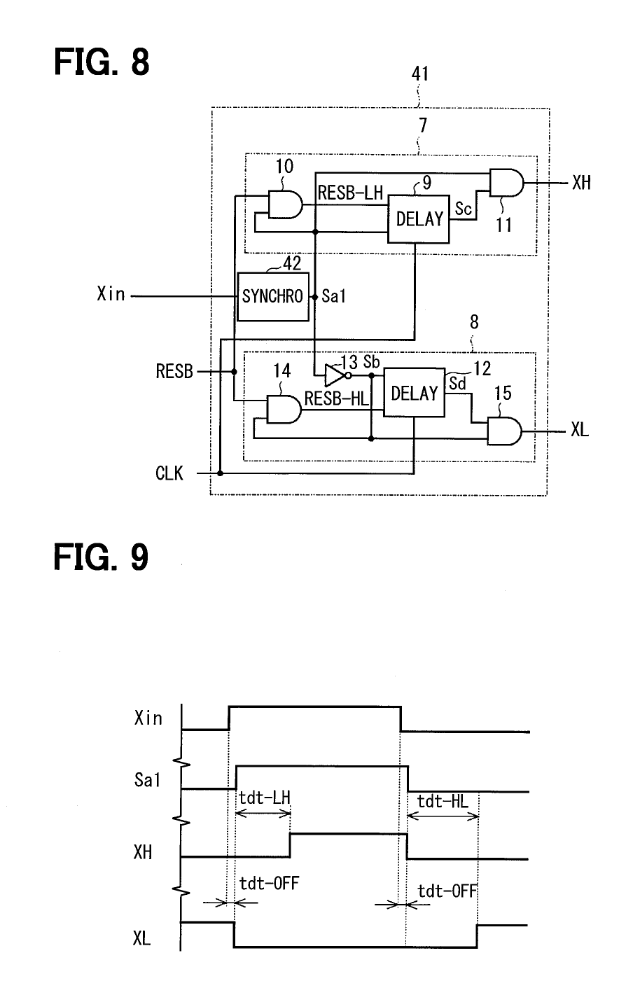

A load driving apparatus according to a second embodiment of the present disclosure will be described with reference to FIG. 8 to FIG. 13. The load driving apparatus according to the present embodiment includes a dead time generation circuit 41 shown in FIG. 8, and the high-side driving circuit 4, the low-side driving circuit 5, and the output circuit 6 shown in FIG. 1. With respect to the dead time generation circuit 3 shown in FIG. 1, the dead time generation circuit 41 is different in that a synchronization circuit 42 is added.

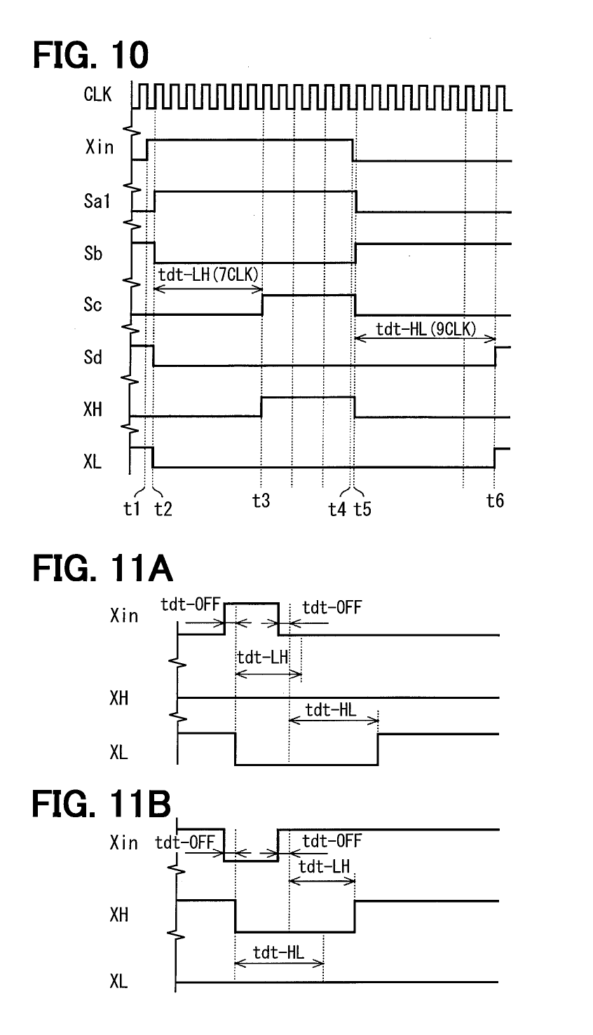

As shown in FIG. 9 and FIG. 10, the synchronization circuit 42 transmits a signal Sa1 which is obtained by synchronizing the control signal Xin with an up-edge of the clock. The signal Sa1 is delayed by a time tdt-OFF, which is less than or equal to 1 clock, from the control signal Xin. When the signal Sa1 rises from the L level to the H level, the delay circuit 12 immediately changes the level of the low-side control signal XL to the L level. The delay circuit 9 uses a rising point of the signal Sa1 as a reference point and changes the level of the high-side control signal XH to the H level after the dead time tdt-LH for 7 clocks, which corresponds to the first clock number, has elapsed from the reference point. As a result, the dead time tdt-LH of the high-side control signal XH has a width of 7 clocks with accuracy.

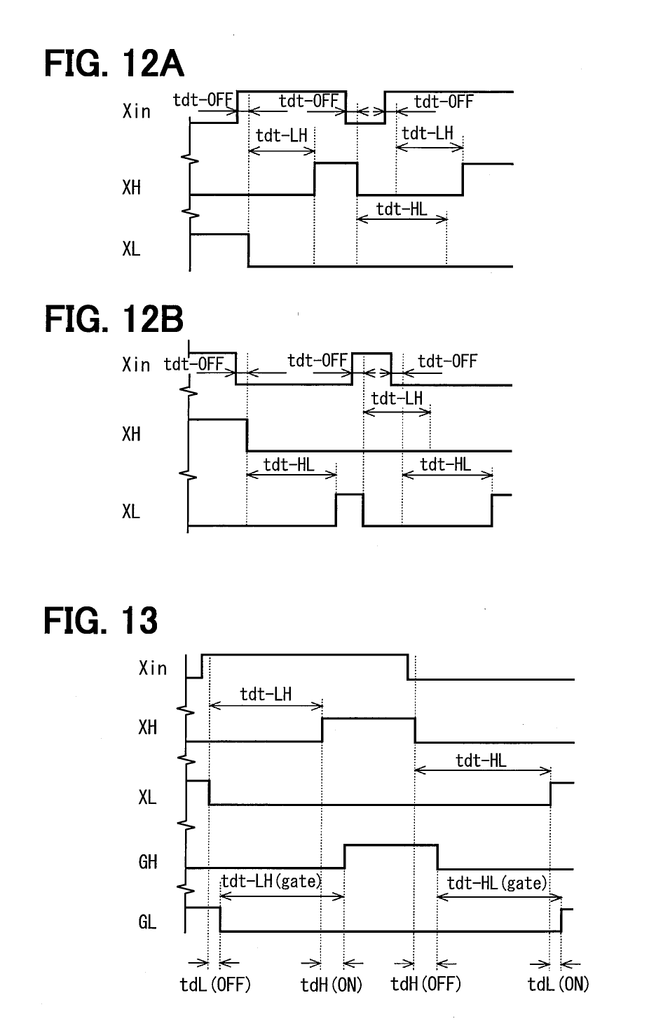

Similarly, when the signal Sa1 falls from the H level to the L level, the delay circuit 9 immediately changes the level of the high-side control signal XH to the L level. The delay circuit 9 uses a falling point of the signal Sa1 as a reference point and changes the level of the low-side control signal XL to the H level after the dead time tdt-HL for 9 clocks, which corresponds to the second clock number, has elapsed from the reference point. As a result, the dead time tdt-HL of the low-side control signal XL has a width of 9 clocks with accuracy. FIG. 11A, FIG. 11B, FIG. 12A, and FIG. 12B are timing diagrams respectively corresponding to FIG. 5A, FIG. 5B, FIG. 6A, and FIG. 6B described in the first embodiment.

FIG. 13 is a diagram used for deriving a condition for equalizing the dead times of the gate signals GH, GL of the IGBTs 19, 20. Also in the present embodiment, the equations (1)-(3) described with reference to FIG. 7 in the first embodiment are satisfied.

As described above, the dead time generation circuit 41 according to the present embodiment includes the synchronization circuit 42 of the control signal Xin. Thus, the dead time tdt-LH and the dead time tdt-HL are respectively equal to the first clock number and the second clock number. As a result, the dead time generation circuit 41 can set the dead times tdt-LH, tdt-HL more accurately than the dead time generation circuit 3 according to the first embodiment. Furthermore, functions and effects similar to the first embodiment can be performed.

### Third Embodiment

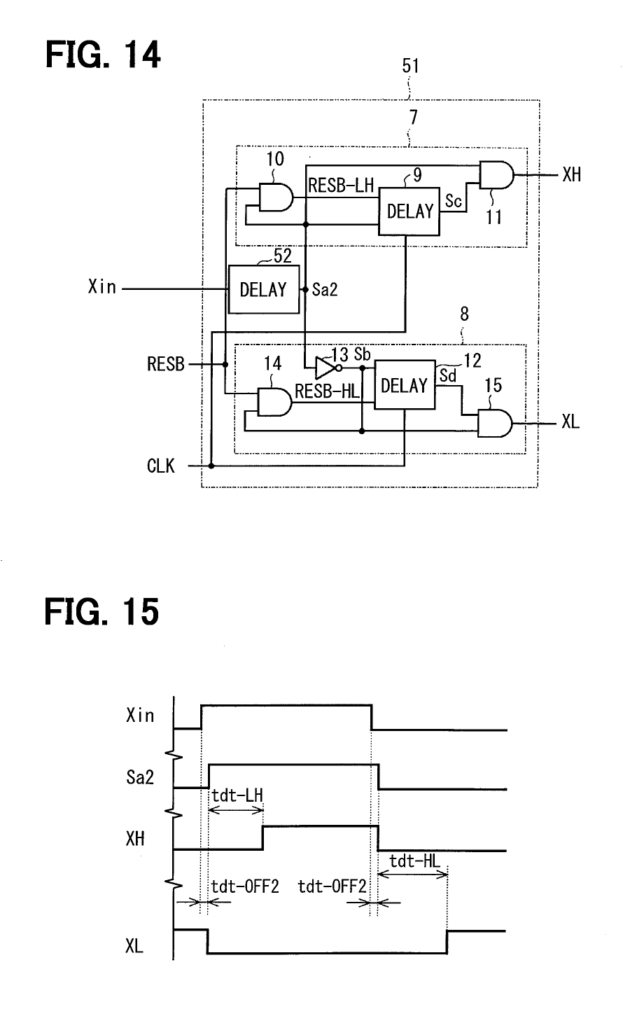

Next, a load driving apparatus according to a third embodiment will be described with reference to FIG. 14 to FIG. 16. The load driving apparatus according to the present embodiment includes a dead time generation circuit 51 shown in FIG. 1, and the high-side driving circuit 4, the low-side driving circuit 5, and the output circuit 6 shown in FIG. 1. In the dead time generation circuit 51, the synchronization circuit 42 in the dead time generation circuit 41 shown in FIG. 8 is replaced by a delay circuit 52 which is a synchronization circuit added with a delay function.

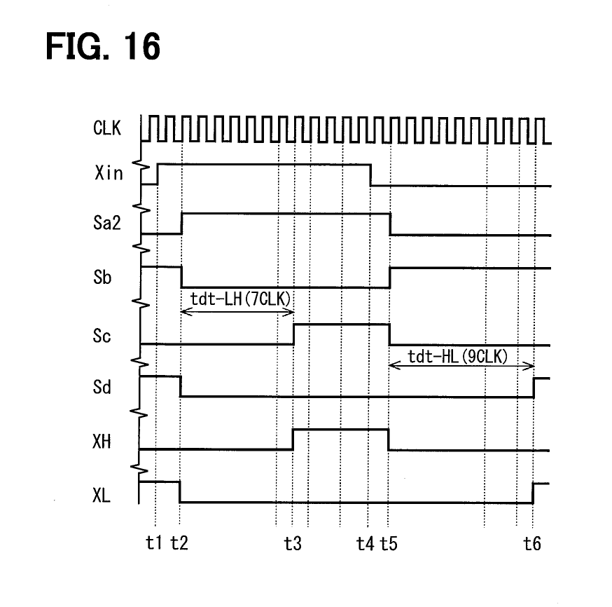

As shown in FIG. 15 and FIG. 16, the delay circuit 52 transmits a signal Sa2 obtained by synchronizing the control signal Xin with an up-edge of the clock and delaying the synchronized signal for a predetermined clock number. The signal Sa2 is delayed for a time tdt-OFF2, which is greater than or equal to the delay clock number and less than (the delay clock number+1), with respect to the control signal Xin. An operation using transition points of the signal Sa2 as reference points are similar to the operation described in the second embodiment. The above-described equations (1)-(3) are satisfied.

The dead time generation circuit 51 includes the delay circuit 52 that synchronizes the control signal Xin. Thus, the dead time tdt-LH and the dead time tdt-HL are respectively equal to the first clock number and the second clock number. As a result, the dead time generation circuit 51 can set the dead times tdt-LH, tdt-HL with accuracy in a manner similar to the dead time generation circuit 41 according to the second embodiment. Furthermore, functions and effects similar to the first embodiment and the second embodiment can be performed.

### Other Embodiments

Although the present invention has been fully described in connection with the exemplary embodiments thereof with reference to the accompanying drawings, it is to be noted that various changes and modifications will become apparent to those skilled in the art. Each of the delay circuits 9, 12 may include multiple stages of D flip-flops having a reset function. In this case, the first clock number and the second clock number can be changed by setting the number of stages appropriately.

The first clock number and the second clock number may be set in view of the turning-on times and the turning-off times of the IGBTs 19, 20 in the output circuit 6 so as to restrict an arm short circuit. The first clock number and the second clock number may be set to values such that the dead times of the high side and the low side appeared in voltage waveforms transmitted from the output terminal 18 are equal to each other. The configurations of the high-side driving circuit 4, the low-side driving circuit 5, and the output circuit 6 can be changed as long as having similar functions.

What is claimed is:

1. A dead time generation circuit comprising:
a high-side control signal generation circuit that controls a level of a high-side control signal to a driving prohibition level when a level of a control signal is a second level and inverts the level of the high-side control signal to a driving permission level when a time corresponding to a first clock number has elapsed in a state where the control signal keeps a first level after the control signal transitions from the second level to the first level; and
a low-side control signal generation circuit that controls a level of a low-side control signal to the driving prohibition level when the level of the control signal is the first level and inverts the level of the low-side control signal to the driving permission level when a time corresponding to a second clock number has elapsed in a state where the control signal keeps the second level after the control signal transitions from the first level to the second level,
wherein the high-side control signal generation circuit and the low-side control signal generation circuit are separate circuits.

2. The dead time generation circuit according to claim 1, further comprising a synchronization circuit that synchronizes the control signal with a clock.

3. The dead time generation circuit according to claim 2,
wherein the synchronization circuit delays the control signal for a predetermined clock number.

4. A load driving apparatus comprising:
the dead time generation circuit according to claim 1;
a high-side driving circuit that receives the high-side control signal transmitted from the dead time generation circuit and transmits a high-side driving signal;
a low-side driving circuit that receives the low-side control signal transmitted from the dead time generation circuit and transmits a low-side driving signal; and
an output circuit including a high-side transistor driven by the high-side driving signal, a low-side transistor driven by the low-side driving signal, driving power lines, and an output terminal, the high-side transistor and the low-side transistor forming a bridge connection between the driving power lines across the output terminal.

5. The load driving apparatus according to claim 4,
wherein the first clock number and the second clock number respectively used in the high-side control signal generation circuit and the low-side control signal generation circuit in the dead time generation circuit are set to values such that a dead time actually appeared in the high-side driving signal when the control signal transitions from the second level to the first level is equal to a dead time actually appeared in the low-side driving signal when the control signal transitions from the first level to the second level.

6. The load driving apparatus according to claim 5,
wherein the high-side driving circuit includes a level shift circuit that changes a voltage level of the high-side control signal, and
wherein the second clock number is longer than the first clock number by a clock number corresponding to a sum of a delay time difference between the high-side driving circuit and the low-side driving circuit at turning on and a delay time difference between the high-side driving circuit and the low-side driving circuit at turning off.
